(19) United States
(12) Patent Application Publication
(10) Pub. No.: US 2010/0282315 A1
(43) Pub. Date: Nov. 11, 2010

(54) LOW CONCENTRATING PHOTOVOLTAIC THERMAL SOLAR COLLECTOR

(76) Inventor: Raymond Gilbert, Saint-Augustin-de-Desmaures (CA)

Correspondence Address: FRASER CLEMENS MARTIN & MILLER LLC, 28366 KENSINGTON LANE, PERRYSBURG, OH, 43551, US

(21) Appl. No.: 12/437,068

(22) Filed: May 7, 2009

(51) Int. Cl. H01L 31/00

(52) U.S. Cl. 136/259

(57) ABSTRACT

A low concentrating solar collector comprising: at least one elongated cross-sectionally V-shape beam, a first and second sunray light reflecting surfaces integral to the respective interior faces of the V-shape beam side legs, at least one of a photovoltaic cell and of a thermal collector member carried by the beam web, the selected photovoltaic cell member and thermal collector member having exposed surfaces accessible to sunrays crossing the V-beam mouth and striking and deflected by the beam side walls light reflecting surfaces toward the beam web. The beam side walls are of such size and composition as to be able to constitute heat sink for optimizing thermal management of the solar collector.

### FIELD OF THE INVENTION

This invention relates to apparatuses for collecting sunlight and transforming same into electricity and/or hot water and/or energy for heat exchanger fluid.

### BACKGROUND OF THE INVENTION

Concentrating solar power (CSP) systems use lenses or mirrors and tracking systems to focus a large area of sunlight into a small beam. The concentrated light is then used as a heat source for a conventional power plant or is concentrated onto photovoltaic surfaces.

Concentrating solar thermal (CST) systems are used to produce renewable heat or electricity (generally, in the latter case, through steam). These CST systems use lenses or mirrors and tracking systems to focus a large area of sunlight into a small beam. The concentrated light is then used as heat or as a heat source for a conventional power plant (solar thermoelectricity). Although a wide range of concentrating technologies exists, the most developed are the solar trough, parabolic dish, and solar power tower. Each concentration method is capable of producing high temperatures and correspondingly high thermodynamic efficiencies, but they vary in the way that they track the Sun and focus light.

A solar trough consists of a linear parabolic reflector that concentrates light onto a receiver positioned along the reflector's focal line. The reflector follows the Sun during the daylight hours by tracking along a single axis. A working fluid (e.g. molten salt) is heated to 150-350° C. as it flows through the receiver and is then used as a heat source for a power generation system. Trough systems are the most developed CSP technology.

A parabolic dish or dish engine system consists of a stand-alone parabolic reflector that concentrates light onto a receiver positioned at the reflector's focal point. The reflector tracks the Sun along two axes. The working fluid in the receiver is heated to 250-700° C. and then used by a Stirling engine to generate power. Parabolic dish systems provide the highest solar-to-electric efficiency among CSP technologies, and their modular nature provides scalability.

A solar power tower consists of an array of dual-axis tracking reflectors (heliostats) that concentrate light on a central receiver atop a tower; the receiver contains a fluid deposit, which can consist of sea water. The working fluid in the receiver is heated to 500-1000° C. and then used as a heat source for a power generation or energy storage system. Power tower development is less advanced than trough systems, but they offer higher efficiency and better energy storage capability.

Concentrating Solar Thermal Power (CSP) can also produce electricity and desalinated water in arid regions.

Concentrating photovoltaics (CPV) systems employ sunlight concentrated onto photovoltaic surfaces for the purpose of electrical power production. Solar concentrators of all varieties may be used, and these are generally mounted on a solar tracker in order to keep the focal point upon the cell as the Sun moves across the sky.

Compared to conventional flat panel solar cells, CPV is advantageous because the solar collector produces more energy (for example 40% more energy) (kilowatt/hour) per installed watt peak than an equivalent area of solar cells. CPV hardware (solar collector and tracker) is targeted to be priced well under 3 USD/Watt, whereas silicon flat panels that are commonly sold are 3 to 5 USD/Watt (not including any associated power systems or installation charges). Semiconductor properties allow solar cells to operate more efficiently in concentrated light, as long as the cell junction temperature is kept cool by suitable heat sinks. CPV operates most effectively in sunny weather since clouds and overcast conditions create diffuse light, which essentially cannot be concentrated.

Low concentration CPV systems are systems with a solar concentration of 2-10 suns. For economic reasons, conventional silicon solar cells are typically used, and, at these concentrations, the heat flux is low enough that the cells do not need to be actively cooled.

From concentrations of 10 to 100 suns, the CPV systems require solar tracking and cooling, which makes them more complex.

High concentration CPV systems employ concentrating optics consisting of dish reflectors or Fresnel lenses that concentrate sunlight to intensities of 200 suns or more. The solar cells require high-capacity heat sinks to prevent thermal destruction and to manage temperature related performance losses. Multi-junction solar cells are currently favored over silicon as they are more efficient. The efficiency of both cell types rises with increased concentration; multi-junction efficiency also rises faster. Multi-junction solar cells, originally designed for non-concentrating space-based satellites, have been re-designed due to the high-current density encountered with CPV (typically 8 A/cm² at 500 suns). Though the cost of multi-junction solar cells is roughly 100 times that of comparable silicon cells, the cell cost remains a small fraction of the cost of the overall concentrating PV system, so the system economics might still favor the multi-junction cells.

Concentrating Photovoltaics and Thermal (CPVT) technology produces both electricity and thermal heat in the same module. Thermal heat that can be employed for hot tap water, heating and heat-powered air conditioning (solar cooling), desalination or solar process heat.

CPVT systems can be used in private homes and increase total energy output to 40-50%, as compared with normal PV panels with 10-20% efficiency, and they produce more thermal heat in wintertime compared with normal thermal collectors. Also, thermal systems do not overheat.

Known system for production of solar energy includes a solar panel, consisting of a photovoltaic, thermal or combined photovoltaic/thermal rotating field positioned usually toward the south, or which rotates to follow the sun in the sky in order to collect the maximum amount of solar energy during the azimuthal and zenithal travel of the sun during the day from when it rises in the east to when it sets in the west.

Solar photovoltaic modules are sensitive to daylight, i.e. to the direct and diffused solar radiation, and therefore, can produce electricity even during a cloudy weather.

Solar photovoltaic modules can be used for autonomous electricity sources, power plants, building integrated elements in new buildings or retrofitting walls and roofs on existing buildings. These modules may also be connected to electrical grid.

In regions with higher insulation with a predominant direct radiation, it is better to use photovoltaic devices with concentrators of solar radiation in the form of Fresnel lenses or linear parabolic mirrors.

Concentration of solar radiation is accompanied by an increase of photovoltaic module temperature and corresponding decrease in conversion efficiency. Therefore, it is preferable to cool them by water or air and/or heat transfer fluid. Also, in order to better utilize the direct component of solar radiation, modules are preferably not stationary but follow the apparent daily movement of the Sun in the sky.

Known free standing interactive systems for production of solar energy include a fixed base, a prism element swiveling on the fixed base and capable of tilting action. The prism element is intended to align itself perpendicularly to the rays of the sun, following the whole arc of zenith from sunrise in the east to sunset in the west and also follow an arc of the azimuth between 0° and 280° corresponding to the range between when the sun rises in the east until it sets in the west. Such systems enable the field of photovoltaic silicon cells/thermal cells to align itself following the path of the sun and as perpendicular as possible to the sun's rays, turning the field along the azimuth between 0° and 280° corresponding to the interval between sunrise in the east and sunset in the west, and turning the field along the zenith between 0° and 90° corresponding to the interval between the position of sunrise and sunset on the horizon and the highest point reached by the sun at midday. That is to say, at all times the rays of the sun fall as perpendicular as possible to the field of silicon cells, and thus rotation on the azimuth from 0° to 280° and tilting along the zenith between 90° (when the sun is on the horizon, at sunrise and at sunset) and 0° (when the sun reaches its highest zenith point at midday). Variations are also taken into consideration due to the seasons of the year, and the (northern or southern) hemisphere where the system is installed.

In these known latter solar collectors, the fixed base supports the swiveling prism on a wheel which enables the prism to turn on the base. The prism swivels along the azimuth form 0° to 280° from east to west, corresponding the path of the sun in the sky, and presents one main face or wall which tilts on the shaft/axis, whose face or wall moves between two extreme positions. This tilting movement of the wall enables it to align itself perpendicular to the rays of the sun between 0° and 90° for displacement along the zenith. The frame constituting and sustaining the field of photovoltaic thermal silicon cells swivels along the azimuth and tilts on the zenith between indicated positions, enabling alignment of the field of silicon cells corresponding to perpendicular incidence of the rays on the wall. The performance of maximum energy uptake depends on the weather as in the event of storm with wind, rain, snow, and the like. In other words, there is double azimuthal and zenithal movement of the unit with respect to the movement of the sun, to align itself at all times as perpendicular as possible to the sun. After the system has completed a daily rotation of 280° very slowly at predetermined intervals, the system performs a reverse movement of 280° during the night to place itself once again in the initial position of 0°, and in the same way, the silicon field of the wall on completing the zenith movement in which it is in a position of 90° performs the return movement up to the 0° position corresponding to the closure of the prism, so that the system closes the prism and rotates the prism with reference to the base frame, so that it is ready for a new cycle of energy collection the next day.

A problem with such prior art solar collector devices is the substantial overhead costs of the main frame structures that support the solar panels. Typically, these support structures represent more than half of the total fixed costs of the solar collectors. This is inefficient.

Another drawback of prior art solar collector devices is that the current state of the art PV panels are relatively small, typically less than 2 square meters of surface. Accordingly, these PV panels cannot be used as structural components for a solar collector device.

A further weakness of prior art solar collector designs is the thermal management of PV panels. Because of additional add-ons required for such thermal management, increased overall costs and weight follow.

### SUMMARY OF THE INVENTION

The invention relates to a low concentrating solar collector comprising: at least one elongated beam element, each beam element having a translucent web, a pair of beam side walls carried by and diverging from said web at bottom edge portions of said beam side walls, and a large open mouth defined between top edge portions of said beam side walls opposite said web, said beam side walls each defining a main inner face in register with one another, each of said beam side walls further forming integral sunray light reflecting surfaces; at least one of a photovoltaic cell member and of a thermal collector member carried by said beam web, the selected photovoltaic cell member and thermal collector member having exposed surfaces accessible to at least infra-red component of sunrays crossing said beam mouth and striking and deflected by said beam side walls light reflecting surfaces toward said web; wherein said beam side walls are of such size and composition as to further be able to constitute a heat sink for optimizing thermal management of said solar collector.

In one embodiment, there could also be further added a first and second mirror members, said first mirror member carried by one of said beam side walls main inner face and said second mirror member carried by the other of said beam side walls main inner face.

Preferably, the plane of each said beam side wall light reflecting surfaces makes an angle of about 11° to 17°, most preferably from 13.5° to 16.5°, relative to a plane orthogonal to that of said beam web, with 15° being the optimal value. The solar collector performance is expected to decrease exponentially when this angular value moves away from 15°.

Preferably, said thermal collector member is a glazed flat plate assembly, most preferably of the 3× concentrator type.

Said beam side walls could be made from aluminium.

It is envisioned to add to the solar collector a sun tracking system operatively connected to said at least one beam element, said sun tracking system continuously maintaining said exposed surface of the selected said photovoltaic cell member and thermal collector member on said beam web in a generally perpendicular orientation relative to the incident sunrays from the sky. Said sun tracking system could then include a self-standing upright ground column having a top end, a bracket mount rotatably mounted to said upright column top end, a slewing drive rotatably driving said bracket mount at said column top end, a planar carrier frame having one and another opposite main faces, means for mounting said bracket mount to said carrier frame for relative movement of the latter relative to said main carrier frame, ram means carried by said bracket means and engaging said carrier frame one main face for tilting the latter relative to said ground column, and anchor means anchoring said web of said at least one beam element to said carrier frame another face.

Preferably, an electronic controller is further provided, automatically controlling the tilt and translation of said carrier frame and associated at least one beam element, to keep said exposed surfaces of selected said photovoltaic cell member and said thermal collector member perpendicular to incident sunrays reflected by said beam side walls light reflecting surfaces.

There could be a plurality of beam elements mounted side by side in said carrier frame another main face and being edgewisely interconnected in successive pairs. The length of each said beam element could also range for example between 3 and 10 meters, the substantially full length of corresponding said web being fitted with selected said photovoltaic cell members and said thermal collector members.

Advantageously, said beam web includes an open pocket projecting opposite said beam side walls and defining an aperture, the selected said photovoltaic cell member and said thermal collector member slidingly releasably engaged through said web aperture into said web pocket.

Said glazed flat plate assembly could include an open casing, engaging said pocket; a thermally insulating block, mounted into said casing at a distance from said beam web wherein a volume of air is formed therebetween, and a number of flow tubes for free flow of heat exchanger fluid, said flow tubes mounted into said insulating block but opening freely into said volume of air spacedly from said beam web.

Alternately, said solar collector could be of a hybrid type, comprising both at least one photovoltaic cell member and at least one glazed flat plate assembly, said photovoltaic cell member fixedly applied directly against and beneath said beam web opposite said beam side walls, said glazed flat plate assembly including an open casing, a thermal insulating block mounted into said casing and directly abutting against said photovoltaic cell member opposite said beam web, and a number of flow tubes for free flow of heat exchanger fluid therethrough, said flow tubes mounted into said insulating block and edgewisely abutting against said photovoltaic cell member for enhancing heat dissipation from the latter.

In another alternate embodiment, said beam web would include an open pocket projecting opposite said beam side walls and defining an aperture, the selected said photovoltaic cell member and said thermal collector member slidingly releasably engaged through said web aperture into said web pocket; and wherein said photovoltaic cell member is fixedly applied directly against and beneath said beam web opposite said beam side walls.

In still another embodiment, there is further provided first and second acrylic/polymer double layer sunray light reflecting membranes, said first membrane carried by one of said beam side walls main inner face and said second membrane-carried by the other of said beam side walls main inner face.

### BRIEF DESCRIPTION OF THE FIGURES OF DRAWINGS

FIG. 1 is a rear elevational view of a ground standing low concentrating photovoltaic thermal solar collector according to one embodiment of the invention, showing the solar collector panel assembly at an approximately 65° angular value relative to a horizontal plane;

FIG. 2 is a view similar to FIG. 1 but at a smaller scale and with the solar collecting panel assembly tilted to a further forwardly downwardly inclined condition relative to the 65° angular value of FIG. 1;

FIG. 3 is a front elevational view of the elements of FIG. 2;

FIG. 4 is a view similar to FIG. 2 but with the solar collecting panel assembly being further tilted to an almost horizontal plane;

FIGS. 5, 5a and 5b are enlarged partly broken perspective views of first, second and third embodiments of part of a V-beam and associated photovoltaic and thermal modules, from the solar collector of FIG. 1;

FIGS. 6, 6A and 6B are end edge elevational views of the V-beam and associated photovoltaic module of the embodiment of FIGS. 5, 5a and 5b respectively;

FIG. 7 is a view similar to FIG. 6, but further showing in cross-section one embodiment of a hybrid solar collector system comprising a thermal collector module and a photovoltaic module, suggesting how the sunrays are deflected by the light reflecting mirror members attached to the inner faces of V-beam side wells, to thereafter strike an absorbing layer beneath the V-beam web;

FIG. 8 is a view similar to FIG. 7, but showing a second embodiment of solar collector limited to a thermal collector module; and

FIG. 9 is an enlarged view of the lower section of FIG. 8, and further showing how the base of the V-beam is anchored to a frame component of the solar collecting panel assembly of FIG. 1.

### DETAILED DESCRIPTION OF THE DRAWINGS

A preferred embodiment of the low concentrating photovoltaic thermal solar collector of the invention is illustrated as 12 in FIG. 14 of the drawings. Collector 12 includes an elongated column 14, supported in upright position over ground by a heavy ground base 16 to which the lower end of column 14 is anchored. To the top end of column 14 is mounted a crown wheel 18. A bracket mount 20 is rotatably carried at a central section 20c of the bracket mount to the crown wheel 18, wherein bracket mount 20 defines a forward section 20a, a rearward section 20b and the central section 20c intermediate sections 20a and 20b. Bracket mount sections 20a, 20b, 20c may extend generally along a horizontal plane.

A slewing drive 19 rotates bracket mount 20 at the top of upright column, about crown wheel 18. A “slewing drive” is a type of worm gear which is used to rotate a load around a shaft. The stewing drive 19 conventionally consists of the crown wheel 18 and of a pinion mounted onto ball bearings, with the pinion and ball bearings mount of the crown wheel 18 actuated by a stepwise electrical motor 43 inside a control box 44. A computer position encoder 45 is further provided. The engine of the slewing drive 19 is connected to controller CPU 47 inside a control panel 44 and using an algorithm to determine in real time the exact position of the sun as a function of the following parameters: date, hour, longitude and latitude data fed thereto. To program this controller CPU 47, the stewing drive 19 is positioned at point “zero” and there is fed to the controller the data that this zero point corresponds to the zero degree horizontal rotation point of bracket mount 20. Hence, the controller 47 will place the bracket mount 20 at this required horizontal position according to the above noted parameters.

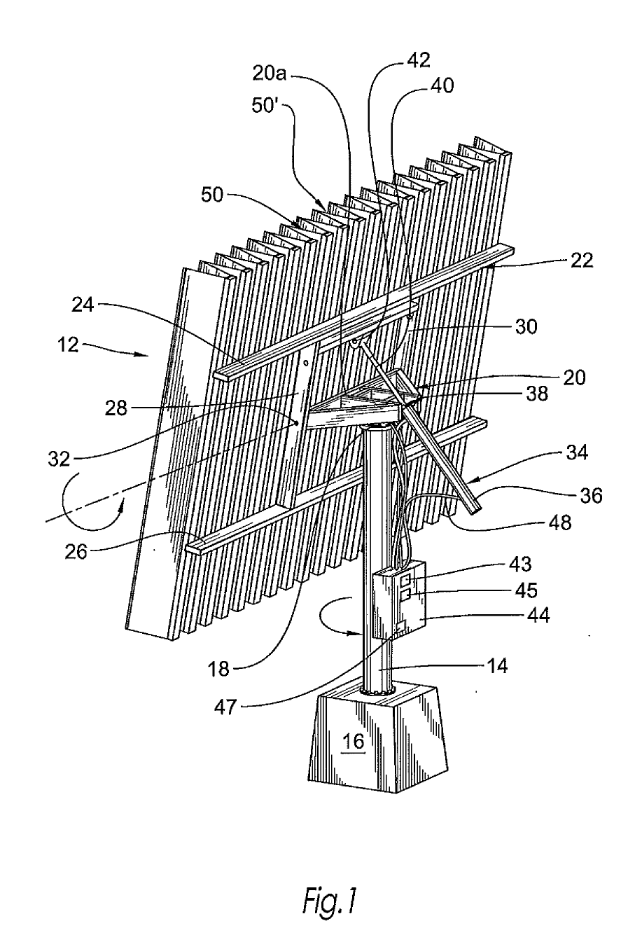

An open frame 22, for example of generally H-shape as illustrated in FIG. 1, is further provided. In the embodiment of FIG. 1, H-shape frame 22 includes a first pair of generally parallel elongated frame elements 24, 26, spaced from one another by a second pair of transverse flame elements 28, 30, spaced from one another. In one embodiment, the size of this H-frame 22 may be for example 675 cm in length and 150 cm in height.

The forward section 20a of bracket mount 20 is sized to fit snugly between the second pair of frame elements 28, 30. A pivot mount 32 pivotally carries the forward section 20a of bracket mount 20 to the second pair of transverse frame elements 28, 30, at a location intermediate first frame elements 24, 26. Ram means 34, for example electrical cylinders also called actuators are further provided for tilt control of the H-frame 22 relative to the column top bracket mount 20. As illustrated in FIG. 1, ram means 34 may include an electrical cylinder 36, pivotally carried at 38 to the rearward section 20b of bracket mount opposite H-frame 22, and a piston rod 40 reciprocatable from the forward end of cylinder 36 and pivotally mounted at generally horizontal pivot axle 42 to top frame element 24 at a location intermediate the pair of second frame elements 28, 30. In this way, as piston rod 40 extends from or retract into cylinder 36, open H-frame 22 will pivot around generally horizontal pivot axle 32.

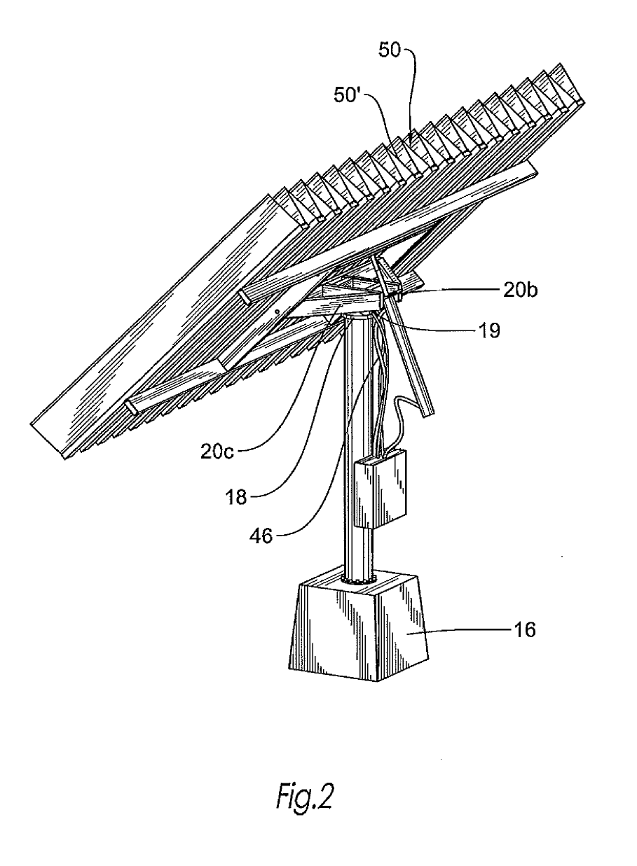

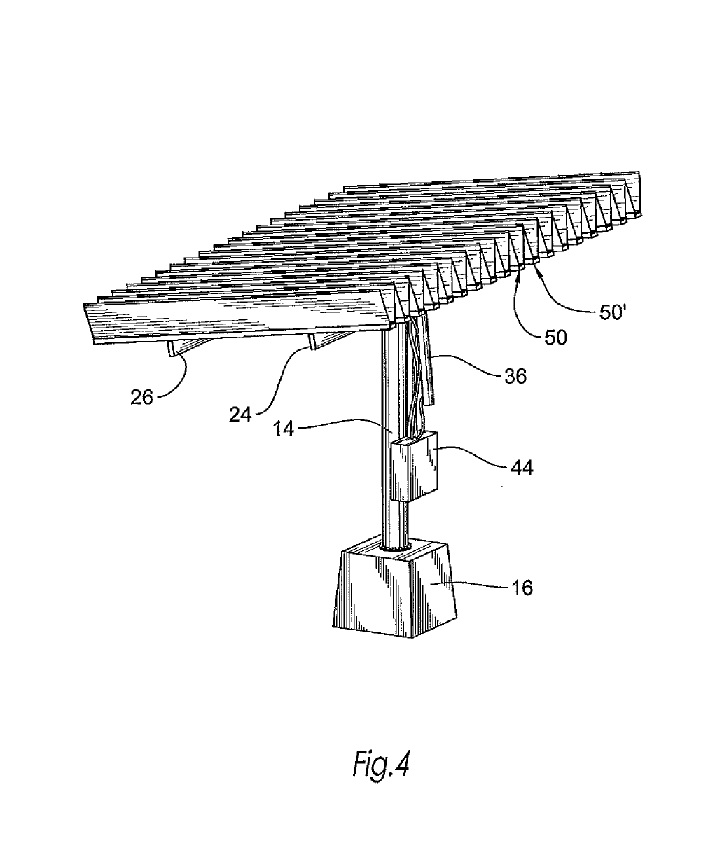

It is thus understood that H-frame 22 will be able both to engage into tilting motion around pivotal axle 32 and into translational motion about crown wheel 18, in such a way that the plane of H-frame 22 may be able to remain substantially perpendicular to the incident solar rays under proper solar tracking during daytime travel of the sun in the sky. In view thereof, electronic controller 47 is fixedly mounted to column 14 and operatively connected to crown wheel 18 by lines 46 and to hydraulic cylinder 36 by lines 48. Controller 47 enables the automatic day by day tilting motion and translational motion of H-frame via ram means 34 and crown wheel 18, respectively for sun tracking purposes, according to known algorithm computations, as suggested by the sequence of FIGS. 1 to 4 of the drawings.

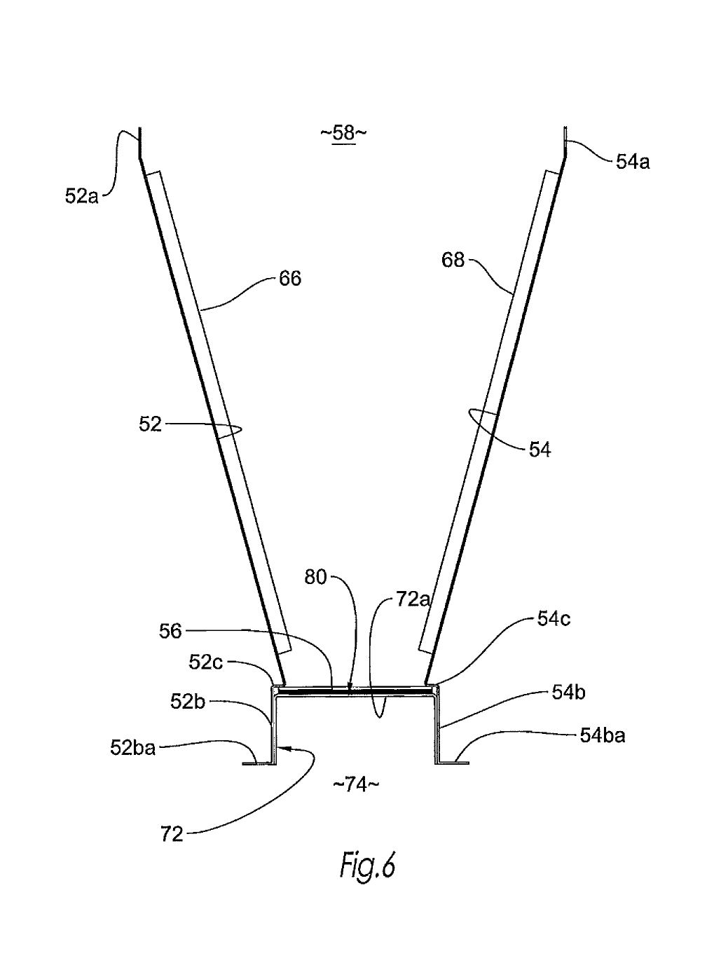

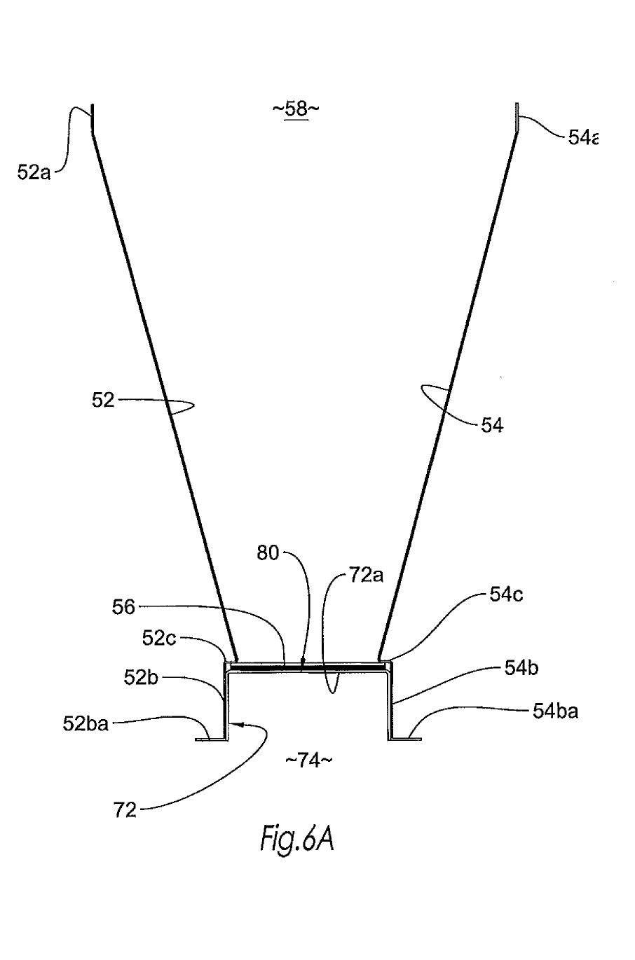

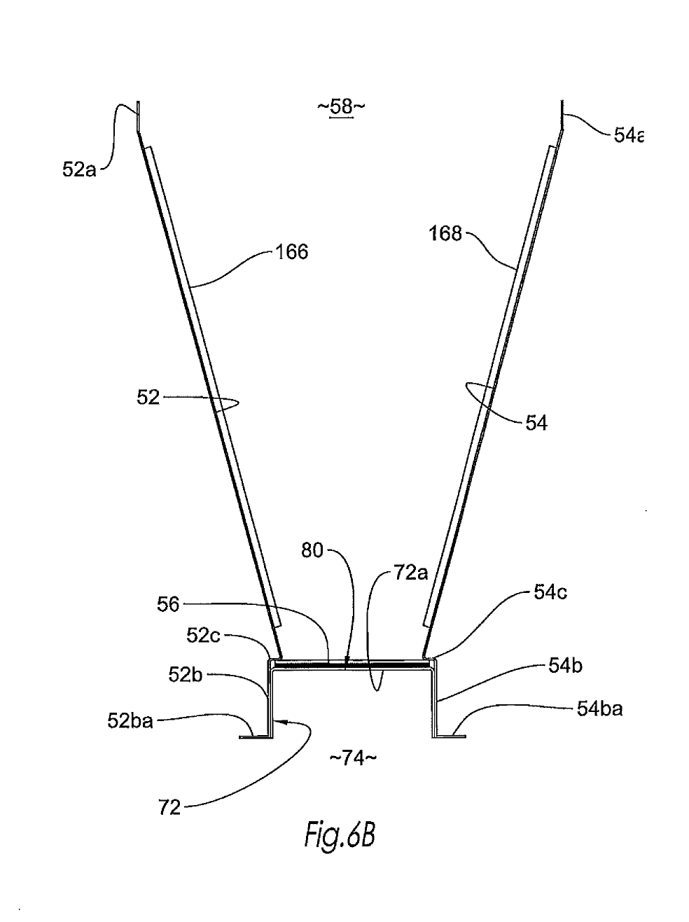

A plurality of elongated beams 50, 50′, 50″, 50′″, etc. . . . is further provided. Each beam 50, 50′, etc. . . . is generally V-shape in cross-section and defines two diverging side walls 52, 54, joined by a narrow base wall or web 56 at the beam web. Web 56 is translucent, preferably transparent to sunray incident light. Each V-beam 50 defines a large mouth 58 formed between the top edge portions 52a, 54a of side walls 52, 54, opposite base wall 56. The width of mouth 58, i.e. the distance between top edge portions 52a, 54a of any given beam 50, is larger than the width of the facing base web wall 56, say for example by about three times as large as web 56, as suggested by FIG. 6 of the drawings. The height of each side wall 52, 54, is greater than the width of base wall 56, for example by about five times as suggested in FIG. 6. Moreover, the length of each beam 50 is much longer than the height of the side legs 52, 54, say for example by about ten times as suggested by FIG. 1 of the drawings.

In one embodiment, the V-beam 50 has a length of 10 meters, a height of 60 cm, a top mouth width of 37.5 cm and a bottom web width of 12.5 cm.

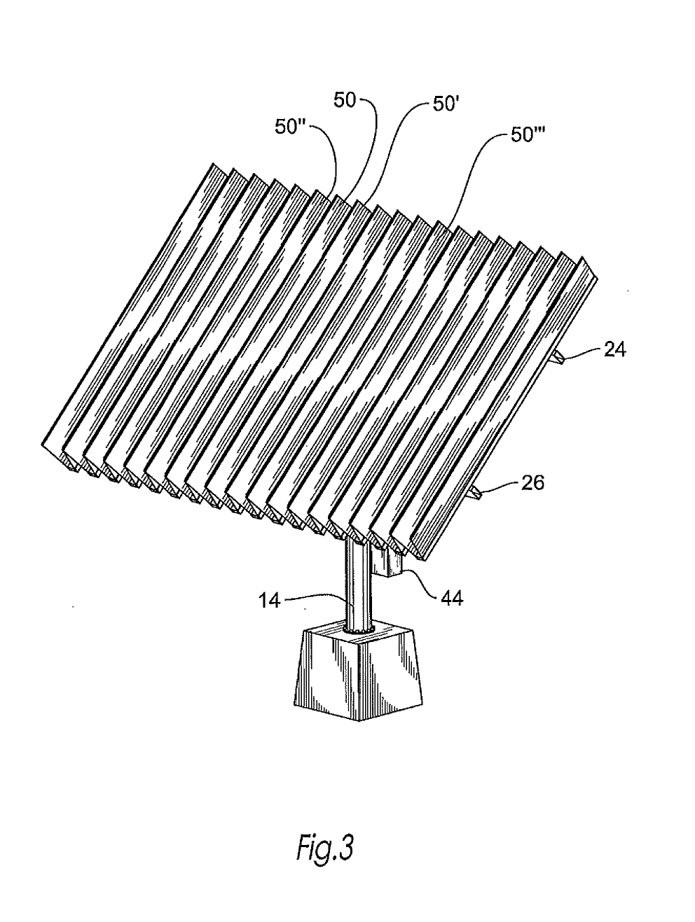

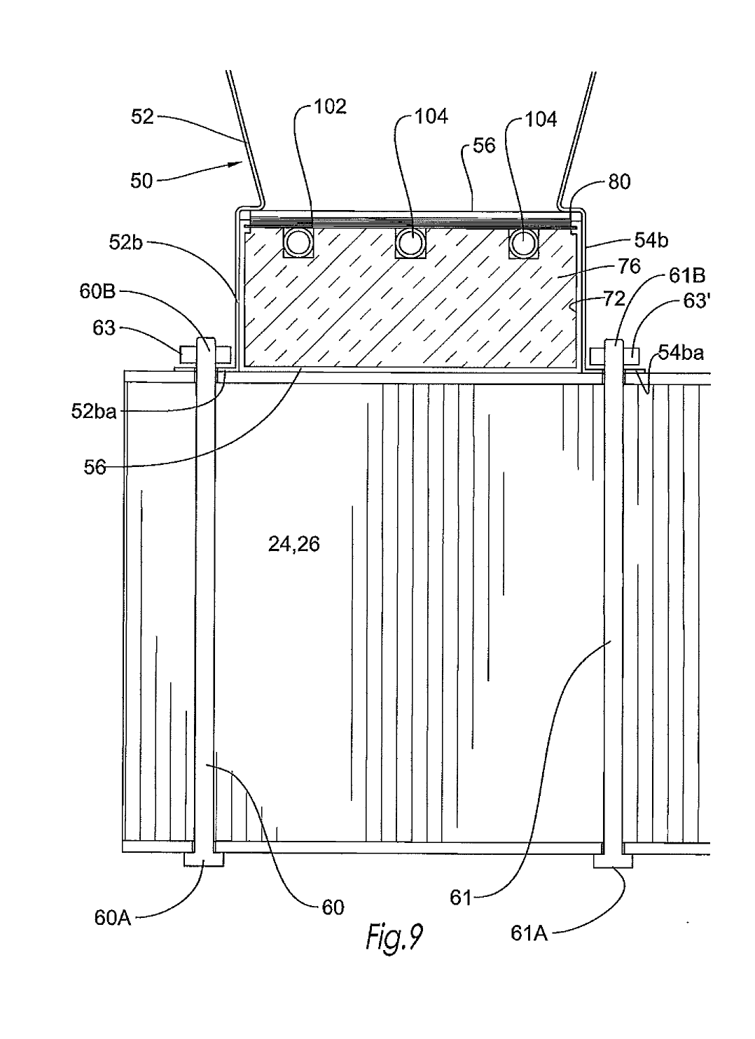

As suggested in FIG. 9, each V-beam 50 further includes a pair of outturned flanges 52ba, 54ba at the bottom edge of side walls 52b, 54b. A pair of elongated bolts 60, 61, extend transversely through support flame legs 24, 26, and extend through corresponding flanges 52ba, 54ba, of a given V-beam 50. The enlarged bottom end heads 60A, 61A abut against one side of frame leg 24, 26, while nuts 63, 63′, fixedly threadingly engage the opposite threaded ends 60B, 61B of bolts 60, 61, to releasably anchor V-beam 50 to support frame legs 24, 26. Each V-beam 50 is thus anchored to legs 24, 26, at two lengthwisely spaced sections of V-beam 50, wherein each V-beam 50, 50′, etc. . . . extends generally orthogonally to support frame legs 24, 26 on the side thereof opposite bracket mount 20. Accordingly, a plurality of V-beams 50, 50′, etc. . . . , for example eighteen (18) V-beams 50 as shown in FIG. 3, can be anchored side by side to frame legs 24, 26, for part of or preferably for the full length of support frame legs 24, 26.

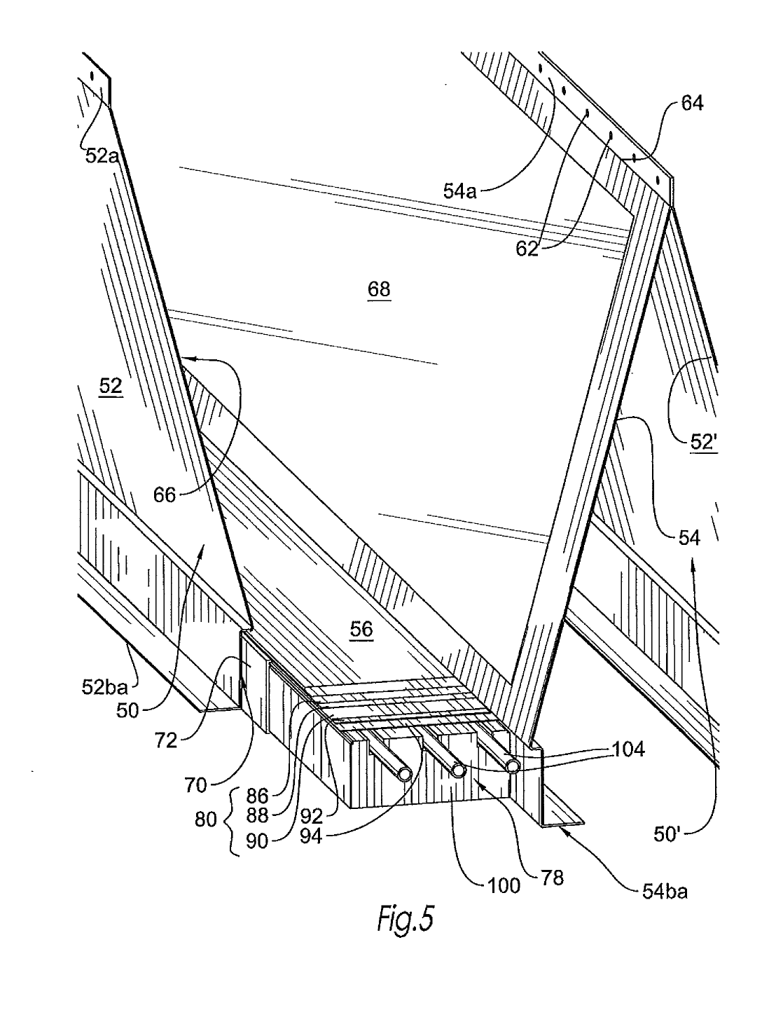

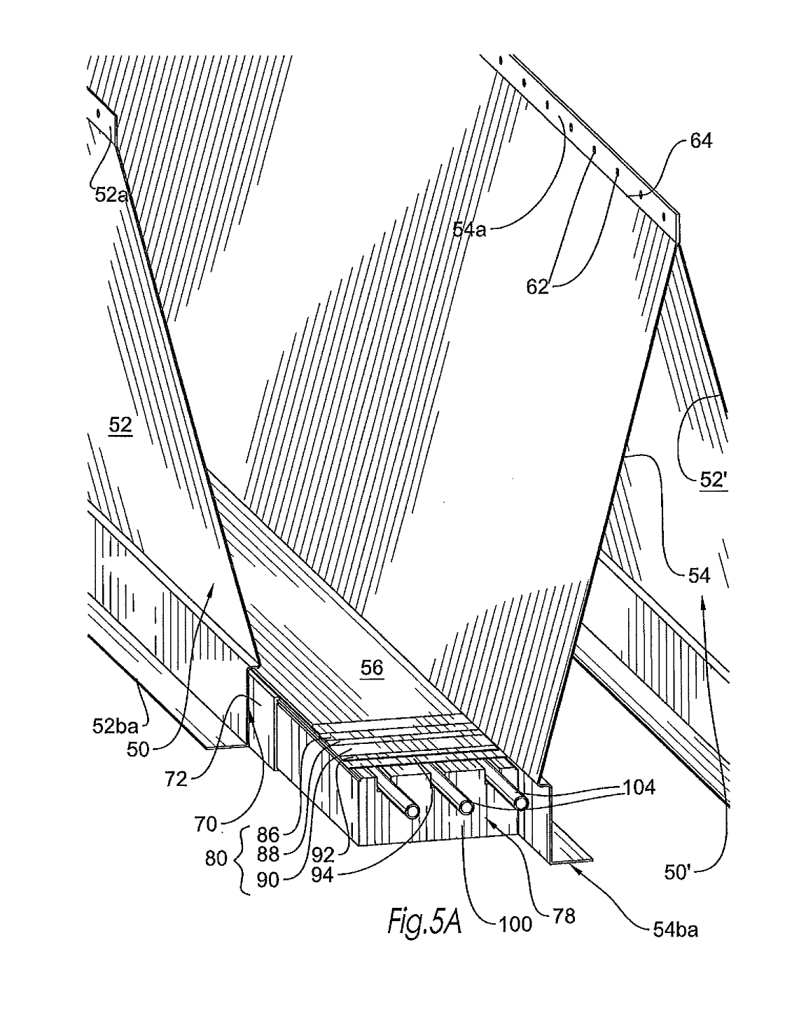

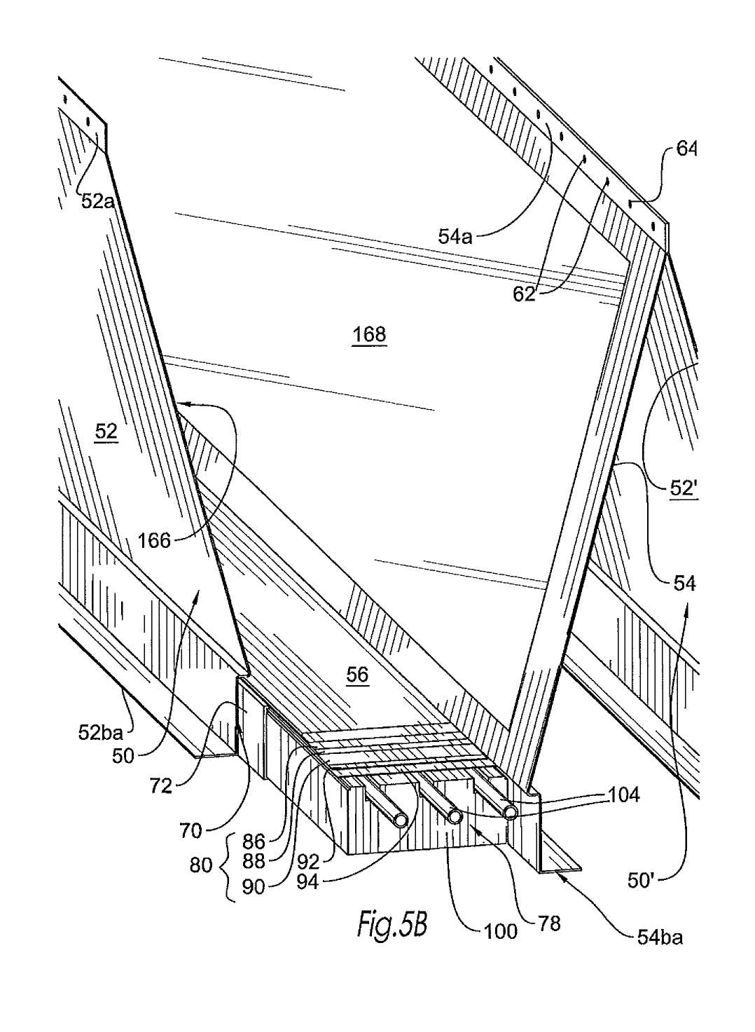

Preferably, as suggested in FIGS. 5 and 6, the top edge portions 52a, 54a, of the V-beam side walls 52, 54, are slightly inwardly elbowed, and have a number of small lengthwisely spaced bores 62 to accommodate rivets 64 to interconnect for example the walls 54, 52′ of adjacent pairs of successive V-beams 50, 50′, in successive pairs, as illustrated.

In one embodiment (FIGS. 5 and 6), the inner face 52d, 54d, of each side wall 52, 54, of V-beam 50 carries a reflecting mirror 66, 68, respectively. Mirrors 66, 68, deflect incoming sun rays passing through upper large V-beam mouth 58 toward lower narrower web 56. Each mirror 66, 68, may be of a size of for example 50 cm×150 cm, being flat and rigid, made for example of aluminium.

In another embodiment (FIGS. 5A and 6A), there is no mirror member, but rather the interior faces of V-beam main side walls 52, 54, themselves define sunray light reflecting surfaces in their own right.

In a third embodiment (FIGS. 5B and 6B), reflecting membranes 166, 168 are applied against the inner face of V-beam side walls 52, 54. Each reflecting membrane 166, 168, may be for example a polymer/acrylic double layer membrane, for example as disclosed in US patent publication No. US/2006/0181765 dated Aug. 17, 2006.

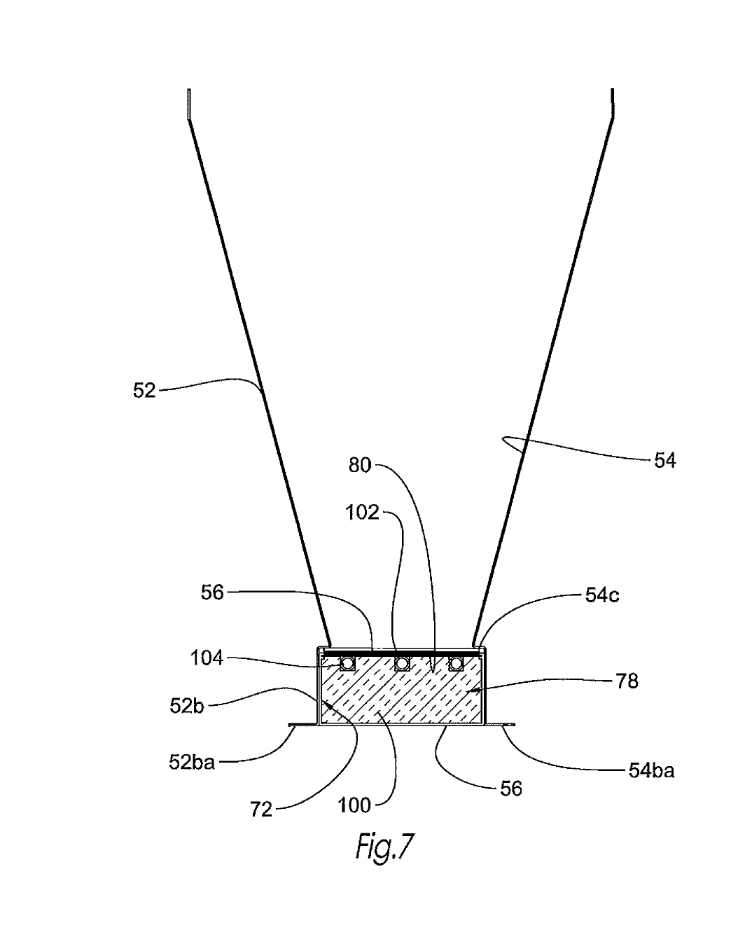

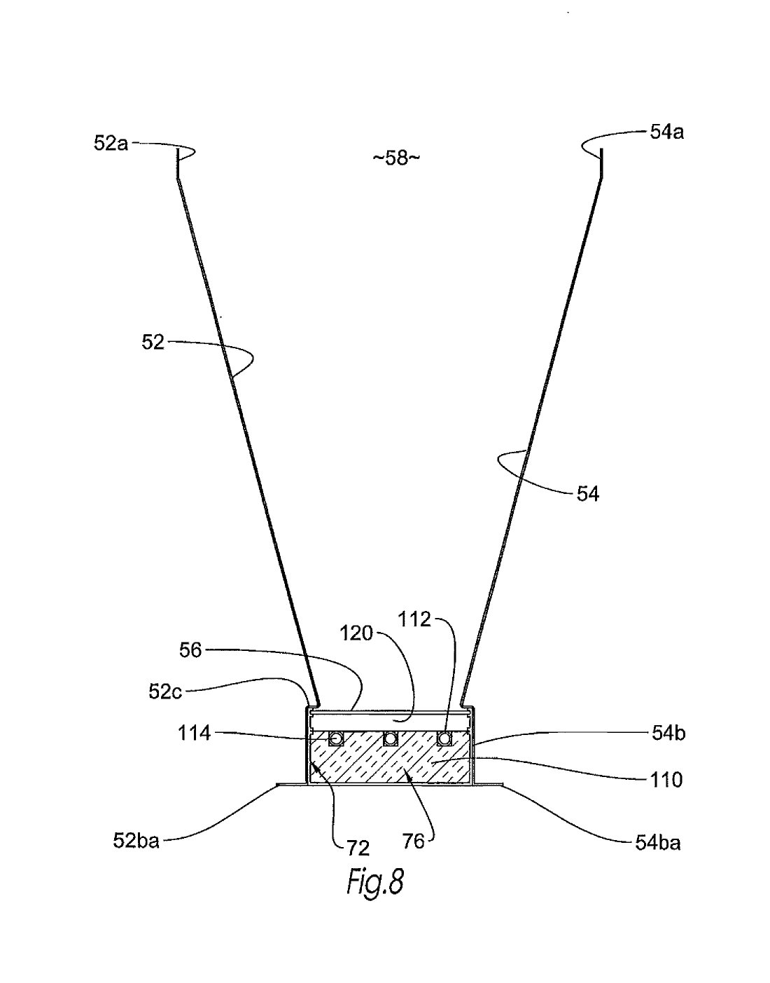

As illustrated in FIGS. 5 to 9, translucid, and preferably transparent web 56 forms a flat surface fixedly joining the lower portions 52b, 54b, of V-beam 50 at inturned elbowed sections 52c, 54c. Beam side walls 52, 54, extend downwardly beyond elbowed sections 52c, 54c, wherein a downwardly opening pocket 70 is formed by web wall 56 and beam side walls lower portions 52b, 54b. This pocket 70 is adapted to receive complementarily sized inversely U-shape casing 72 in releasable friction fit sliding fashion. U-shape casing 72 thus defines a bottom mouth 74. U-shape casing 72 made e.g. from aluminum is releasably slidingly frictionally engageable through mouth 74 by a solar collector module consisting of either:
a thermal collector module such as a glazed flat plate assembly 76 integral into 3× structure so as to lead to lower costs (see FIG. 8);
a combined or “hybrid” module comprising both a thermal collector unit 78 and a photovoltaic cell unit 80 (see for example FIGS. 5 and 7); or
a photovoltaic cell unit 80 (see FIG. 6).
   Inversely U-shape casing 72 could also accommodate one or more photovoltaic cell units 80 exclusively of thermal collector module, but in that case, the photovoltaic cell units 80 will be taken in sandwich between the web 72a of casing 72 and the web 56 of beam 50, as shown in FIG. 6.
   FIG. 5 shows the various layers of the photovoltaic cell, namely:
a top exposed low iron glass 86;
EVA 88;
photovoltaic (PV) cells 90;
EVA 92; and
PET or Tedlar 94 (a plastic sheet for voltage standoff, for electrical insulation).
   All these layers are laminated to form a photovoltaic module.

The photovoltaic (PV) cell is fixedly connected to the top copper or aluminum flat plate of the thermal collector, e.g. with double tape, glue, conductive epoxy, or heat sink compound.

In one embodiment, the size of the PV module is 12.5 cm×150 cm, using a plurality of 4.17 cm×12.5 cm PV cells having an efficiency of 17%. These cells are assembled in strings comprising about 34 cut cells, being electrically series connected.

In one embodiment, the size of each thermal module is 12.5 cm×150 cm.

As illustrated in FIG. 9, the PV module and thermal collector assembly, or “hybrid” solar module, fits against an outturned elbowed section of the lower section of the two facing mirrors. This elbowed section forms a flat seat against which the top exposed low iron glass layer of the solar module edgewisely abuts and is sealed thereto with an aluminum glue sealing joint.

Thermal collector unit in FIGS. 5 and 7 includes a thermally insulating main block 100, having lengthwise top notches 102 through which run heat exchanger fluid flow pipes 104, such as flow tubes from glazed flat plate collector assemblies, as illustrated. These fluid flow pipes 104 enable proper thermal management of excess heat generated by sunrays at the level of photovoltaic cells 80 by thermal dissipation, through dissipating of excess heat by free flow of the head exchanger fluid therethrough. Flow pipes 104 may be made e.g. from copper or aluminum.

Glazed flat plates are used to generate hot water or heat exchanger fluid. When a glazed flat plate assembly is exposed to sunlight, about 30% of solar energy is reflected while 70% is absorbed by the absorbing element of the glazed flat plate. The absorber will then transfer this energy to a thermal exchange fluid which runs through the pipes mounted to the absorber. Clearly, the efficiency of a glazed flat plate is a function of its thermal insulation and of the difference between ambient temperature and temperature of the thermal exchange fluid.

Also, the present invention has led to the unexpected and surprising discovery that the combination of a glazed flat plate inside a 3× concentrator, such as our V-beam 50, enables to heat warm fluid (for example, water) even during sub-freezing winter temperatures Indeed, concentrated glazed flat plates are very well adapted to the winter weather conditions of subpolar countries such as Canada. Therefore, hot water can be generated in cold climates even during winter time, and with that a very low cost since the present glazed flat plates are three times smaller and thus cost three times less than standard glazed flat plates. In the present invention with clear skies during the day, one can generate 75° C. hot water with a 50% efficiency even when ambient temperature is minus 10° Celsius.

Thermal collector unit 76 in FIG. 8 also includes a thermally insulating main block 110 having lengthwise top notches 112 through which run heat exchanger fluid flow pipes 114 as above noted. However, main block 110 and pipes 114 extend upwardly short of translucent web 56, so that an air volume 120 is formed and trapped therebetween. As illustrated in the embodiment of FIG. 8, the free volume of air between the glass and the absorbing element is very important, since it is this volume of air which increases the panel thermal insulation and increases its performance.

Accordingly, contrary to prior art solar collector designs, in one embodiment, it is the aluminum structure 52, 54, itself which constitutes the reflecting mirrors, and/or the mirror themselves 66, 68 in another embodiment, or the reflecting membranes 166, 168, in the third embodiment of the invention.

In the embodiment of FIGS. 5 and 6, the mirrors 66, 68, are glued to the walls 52, 54, of the cross-sectionally V-shape beam 50. There results not only reduced overhead costs, but also reduced assembly time in the field. The mirrors 66, 68, are tied together in an array, and the mirror array is screwed down onto the metallic casing 72 that surrounds the laminated circuit, completing the 3× mirror module. This feature allows for mirror replacement if required over time.

Moreover, if after a certain period of time, one wants to modify the collector system carried by the cross-sectionally V-shape beam, conversion is easily and quickly done, by simply downwardly withdrawing the photovoltaic unit 80 and/or thermal collector unit 76 or 78 slidingly from inversely U-casing 72.

In all embodiments, the present cross-sectionally V-shape aluminum beam 50 is used as a support beam and as containing unit for other components. This feature cannot be found in prior art solar collectors.

The present invention is not limited to self standing support application, and may extend to other applications such as in a building, a greenhouse, on a swimming pool, on solar fields and the like.

The present invention can work even in sub-freezing temperatures. Indeed, any snow or freezing rain that may build up on the beam web 56 will thaw and drip down, thanks to the thermal collector units 76 or 78. With prior art conventional PV panels, on the contrary, accumulated snow and ice did not thaw during normal operations.

In the present invention, each cross-sectionally V-shape beam 50 has several features:
1. it contains all of the photovoltaic components, thermal components, and mirrors or membranes;
2. it serves as a 3× type solar concentrator (thus decreasing by 3 times the required size of the photovoltaic components);
3. it serves as a support beam;
4. it serves as a heat sink, to dissipate excess heat about beam side walls 52, 54, when the present invention is used solely as an electrical photovoltaic solar energy collecting system.
5. a solar converter combining on the same surface of a structural component an electrical converter and a thermal converter;
6. preferably, a photovoltaic component made of 4.16 cm×12.5 cm assembled in “string” of 1.5 meters in length, so as to enable efficient electrical conversion into the 3× type concentrator and to enable transfer of thermal losses to the thermal component;
7. the thermal collector unit is operatively connected to the photovoltaic component so as to dissipate excess heat while lowering its operating temperature thus increasing the photovoltaic cell efficiency.

It is noted that prior art frames for PV panels only support the glass, they are not structural elements.

In conclusion, the present solar collector may be used in three different fashions:

in a hybrid mode, comprising at least one PV member and one thermal collector members. In a hybrid mode, the thermal collector may be used to heat water or any other heat transfer fluid. It may also be used to cool the PV unit through the circulation of a heat transfer fluid which is maintained at a temperature below 35° C. by using radiators of the same type than those used to cool a car engine.

In an electrical mode only, comprising only a PV component, one of the mirrors 66, 68, and/or associated beam side wall 52, 54, are used as a heat sink, for excess heat dissipation.

It has been found that unexpectedly, an important part of diffused ambient light can be economically collected if an angle of about between 11° to 17°, preferably from 13.5° to 16.5°, with optimal value of 15° is used between the PV panels and a plane orthogonal to that of the reflecting mirrors 66, 68 or the light reflecting interior surfaces of the beam side walls 52, 54, or that of membranes 166,168. This angular value is very important. For example, if instead of using 15°, we use a 23° angle, for example, this reduces the overall efficiency by 20%. It is this angle of 15° which determines the height of the upright column. Indeed, if 12.5 cm cells are used, and we want a 3× effect, one needs to have a mouth 58 of a size of 37.5 cm between the top edges of each pair of diverging mirrors 66, 68 or membranes 166, 168. Hence, the only way to achieve a design where the width of the web base 56 is 12 cm and the width of the top end mouth 58 is 37.5 cm is with a 15° angle between the two, by using mirrors 66, 68 having 50 cm in length.

Since the V-beam 50 may extend over substantial area in space, its efficiency to dissipate excess heat in space and to reduce operational temperature of the PV elements is very high.

1. A low concentrating solar collector comprising:
at least one elongated beam element, each beam element having a translucent web, a pair of beam side walls carried by and diverging from said web at bottom edge portions of said beam side walls, and a large open mouth defined between top edge portions of said beam side walls opposite said web, said beam side walls each defining a main inner face in register with one another, each of said beam side walls further forming integral sunray light reflecting surfaces;
at least one of a photovoltaic cell member and of a thermal collector member carried by said beam web, the selected photovoltaic cell member and thermal collector member having exposed surfaces accessible to at least infra-red component of sunrays crossing said beam mouth and striking and deflected by said beam side walls light reflecting surfaces toward said web;
wherein said beam side walls are of such size and composition as to further be able to constitute a heat sink for optimizing thermal management of said solar collector.

2. A solar collector as in claim 1,
further including a first and second mirror members, said first mirror member carried by one of said beam side walls main inner face and said second mirror member carried by the other of said beam side walls main inner face.

3. A solar collector as in claim 1,
wherein the plane of each said beam side wall light reflecting surfaces makes an angle of between about 11° to 17° relative to a plane orthogonal to that of said beam web.

4. A solar collector as in claim 1,
wherein said thermal collector member is a glazed flat plate assembly.

5. A solar collector as in claim 4,
wherein said thermal collector member is of the 3× concentrator type.

6. A solar collector as in claim 1,
wherein said beam side walls are made from aluminium.

7. A solar collector as in claim 1,
further including a sun tracking system operatively connected to said at least one beam element, said sun tracking system continuously maintaining said exposed surface of the selected said photovoltaic cell member and thermal collector member on said beam web in a generally perpendicular orientation relative to the incident sunrays from the sky.

8. A solar collector as in claim 7,
wherein said sun tracking system includes a self-standing upright ground column having a top end, a bracket mount rotatably mounted to said upright column top end, a slewing drive rotatably driving said bracket mount at said column top end, a planar carrier frame having one and another opposite main faces, means for mounting said bracket mount to said carrier frame for relative movement of the latter relative to said main carrier frame, ram means carried by said bracket means and engaging said carrier frame one main face for tilting the latter relative to said ground column, and anchor means anchoring said web of said at least one beam element to said carrier frame another face.

9. A solar collector as in claim 8,
further including an electronic controller, automatically controlling the tilt and translation of said carrier frame and associated at least one beam element, to keep said exposed surfaces of selected said photovoltaic cell member and said thermal collector member perpendicular to incident sunrays reflected by said beam side walls light reflecting surfaces.

10. A solar collector as in claim 9,
wherein there is a plurality of beam elements mounted side by side in said carrier frame another main face and being edgewisely interconnected in successive pairs.

11. A solar collector as in claim 10,
wherein the length of each said beam element ranges between 3 and 10 meters, the substantially full length of corresponding said web being fitted with selected said photovoltaic cell members and said thermal collector members.

12. A solar collector as in claim 4,
wherein said beam web includes an open pocket projecting opposite said beam side walls and defining an aperture, the selected said photovoltaic cell member and said thermal collector member slidingly releasably engaged through said web aperture into said web pocket.

13. A solar collector as in claim 12,
wherein said glazed flat plate assembly includes:
an open casing, engaging said pocket;
a thermally insulating block, mounted into said casing at a distance from said beam web wherein a volume of air is formed therebetween, and
a number of flow tubes for free flow of heat exchanger fluid, said flow tubes mounted into said insulating block but opening freely into said volume of air spacedly from said beam web.

14. A solar collector as in claim 12,
wherein said solar collector is of a hybrid type, comprising both at least one photovoltaic cell member and at least one glazed flat plate assembly, said photovoltaic cell member fixedly applied directly against and beneath said beam web opposite said beam side walls, said glazed flat plate assembly including an open casing, a thermal insulating block mounted into said casing and directly abutting against said photovoltaic cell member opposite said beam web, and a number of flow tubes for free flow of heat exchanger fluid therethrough, said flow tubes mounted into said insulating block and edgewisely abutting against said photovoltaic cell member for enhancing heat dissipation from the latter.

15. A solar collector as in claim 1,
wherein said beam web includes an open pocket projecting opposite said beam side walls and defining an aperture, the selected said photovoltaic cell member and said thermal collector member slidingly releasably engaged through said web aperture into said web pocket; and wherein said photovoltaic cell member is fixedly applied directly against and beneath said beam web opposite said beam side walls.

16. A solar collector as in claim 3,
wherein the plane of each said beam side wall light reflecting surfaces makes an angle of between 13.5° to 16.5° relative to a plane orthogonal to that of said beam web.

17. A solar collector as in claim 1,
further including first and second acrylic/polymer double layer sunray light reflecting membranes, said first membrane carried by one of said beam side walls main inner face and said second membrane carried by the other of said beam side walls main inner face.

18. A solar collector as in claim 16,
wherein the plane of each of said beam side wall reflecting surfaces makes an angle of 15° relative to a plane orthogonal to that of said beam web.
